(19) United States
(12) Patent Application Publication
(10) Pub. No.: US 2010/0117199 A1
(43) Pub. Date: May 13, 2010

(54) METHOD AND APPARATUS FOR THE PRODUCTION OF THIN DISKS OR FILMS FROM SEMICONDUCTOR BODIES

(76) Inventor: Christopher Eisele, Tittmoning (DE)

Correspondence Address: K.F. ROSS P.C., 5683 RIVERDALE AVENUE, SUITE 203 BOX 900, BRONX, NY, 10471-0900, US

(21) Appl. No.: 12/596,149

(22) PCT Filed: Oct. 15, 2008
(86) PCT No.: PCT/DE2008/000628

§ 371 Date: Oct. 22, 2009

(30) Foreign Application Priority Data
Apr. 17, 2007 (DE) 10207018080.4

(51) Int. Cl. H01L 29/02; B26D 7/06

(52) U.S. Cl. 257/618; 83/23; 83/78; 257/E29.002

(57) ABSTRACT

The invention relates to a method and an apparatus for the production of thin disks or films (3) from semiconductor bodies (1). Advantageously, a laser is used as a cutting tool (2). The beam of the laser is focused using suitable optical means, for example a cylindrical lens, in such a way that a linear intensity profile is created rather than a point-shaped one in order to cut the semiconductor film (3). Furthermore, it is meaningful to place several linear intensity profiles in a row in such a way that a parting line is created across the entire width of the semiconductor body (1), such that the entire cutting line can be removed quasi continuously, at the repetition rate of the laser. Ideally, the peripheral beams of the focused laser beam, which face the semiconductor body (1), should extend parallel to the edge of the semiconductor body (1). Near the tip (9) of the cutting tool (2), on the side facing the semiconductor film (3), the peripheral beams follow the bending radius of the semiconductor film (3), and an increasing gap is created as the distance from the focus (the tip of the cutting tool 2) increases.

The present invention relates to a method and an apparatus for the production of thin disks or films from semiconductor bodies such as polycrystalline blocks (ingots) or monocrystalline rods.

Wire saws are usually used for cutting brittle-hard workpieces (e.g. silicon). Essentially, two methods are used (description DE 19959414). In parting-off by lapping, a slurry is used, while in the parting-off grinding process, the cutting grains are firmly attached to the wire. It is the case for both methods that the cutting process takes place by means of a relative motion between the wire and the workpiece. This relative motion is obtained in DE 19959474 by the fact that the workpiece is turned about its longitudinal axis. Usually the wire is moved and guided, for example with the help of deflection rollers, repeatedly by the workpiece so that many disks can be simultaneously detached. In the parting-off grinding process with brittle diamond wire saws, gating multi-wire saws (DE 19959414) are suited deflection, because the wire is not mechanically loaded by the deflection.

For the production of silicon disks with a thickness of approximately 200 μm for the photovoltaic industry, wire saws are used predominantly at present. At the same time the minimal sawing gap is limited by the wire diameter and the slurry.

The splitting of mono-crystalline silicon rods such as described in US 2004055634, can be an interesting alternative for the production of silicon wafers. At the same time the outer surface of a silicon rod is locally irradiated with an ion beam, electron beam or laser beam, in order to produce targeted lattice defects. This preferably occurs along a line that is defined by the crystal axes, so that the subsequent split plane corresponds to a crystal lattice plane. The splitting process takes place for example by means of mechanical shear forces along the lattice defects produced. In the splitting process, no cutting losses are produced. Further advantages are clean split surfaces, a fast splitting process, as well as very even surfaces. US 2004055634 indicates a potential utilization of 10,000 wafers per meter of silicon rod length.

If a laser beam is used to locally heat the outer surface of the silicon rod, the vacuum environment can be dispensed with. In DE 3403826, a method is described in which a notch in the groove encircling the outer surface is locally heated in a targeted manner. Using a temperature shock treatment, the disk is subsequently blasted away from the rod. Due to the mechanical processing of the notch however, it is to be expected that the thickness of the silicon disk has a lower limit.

In JP 2002184724, the outer surface is locally heated with a focused excimer laser beam. Both the last-named methods require a single crystal as a starting material, as in US 2004055634. For cutting methods involving splitting, it therefore remains open whether an economic application can be realized for the production of thin semiconductor disks in future.

US 2005199592 also describes a cutting method for cutting silicon by means of laser radiation. This however concerns the cutting of silicon disks into individual chips. To do this, an Nd:YAG laser (1064 nm) is focused in such a way that the focus lies in the interior of the disk. This leads to micro-cracks, which by means of a suitable arrangement become predetermined breaking points for the disk. If in addition a notch is mechanically produced on the surface with a diamond tool or with a laser, the breakage line can be defined line still more precisely. The disk can now be broken by mechanical stress along the previously defined lines. US 2005199592 describes how disks with a thickness of for example 625 m can be split. For this disk thickness the breaking edge can be defined in a targeted manner, but the method does not scale up to arbitrary material thicknesses, since the working distance of the focusing optics and the absorption of the laser radiation limit the penetration depth.

Usually the material processing works with focused laser beams, in which the working range is restricted to the immediate environment of the focus. DE 19518263 describes an apparatus for material processing, in which the laser radiation is guided on to the material surface in a liquid jet. In addition, by means of a special nozzle the focused laser beam is coupled into the fluid jet that is as laminar as possible. This method can also be applied in the cutting of silicon disks. Here, cut widths of typically 50 μm are obtained, which are determined essentially by the fluid jet. It has been observed with this method however that, in spite of the use of nanosecond pulses, melt zones arise, which can adversely affect the mechanical stability of the workpieces after re-solidification.

The melt zones can be markedly reduced if the device is operated with shorter laser pulses. DE 10020559 cites the following advantages for material processing with ultra-short laser pulses. “The particular advantages of material processing with ultra-short laser pulses (fs laser pulses) are revealed in particular in the extremely precise cutting and/or removal of materials that also causes minimal thermal and mechanical damage. Removal rates in the sub-μm range can be obtained with cut widths of less than 500 nm”. The thermally and mechanically minimally damaging processing represents the decisive advantage over processing with nanosecond pulses.

The small cutting widths can only be attained however when working within the limited focus depth. In the case of larger cut depths, the cut line width increases accordingly, on account of the beam focusing.

It is known that silicon can also be processed with femtosecond laser pulses so as to utilize the advantages cited above. Bärsch et al., obtained a cut line width of 10-15 μm when splitting a silicon disk 50 μm thick. They were also able to show that a linear beam profile aligned along the cut line leads to an increased removal rate in comparison to point-shaped beam profiles. For narrow cut lines, the working range remains limited to the spatially restricted area around the focus. Hence narrow cut line widths cannot be realized in the production of rigid silicon disks.

The task addressed by the present invention is to disclose a method for the production of thin semiconductor films, in particular silicon films, by cutting semiconductor bodies, and an apparatus for carrying out this method.

This problem is solved by a method in accordance with claim 1 and by an apparatus in accordance with claim 15.

While a brittle-hard material, such as a semiconductor material, is per se largely stiff and brittle, the method according to the invention advantageously and in a targeted manner uses the property that semiconductor disks become ever more flexible, the thinner they are.

A method for the production of thin semiconductor films, in particular silicon films, by cutting of semiconductor bodies using a cutting tool, is especially advantageous if the following method steps are executed:

a. provision of a semiconductor body;

b. moving a cutting tool close to the semiconductor body;

c. introducing a relative movement between semiconductor body and cutting tool for the successive detachment of the semiconductor film from the semiconductor body;

d. bracing the already freely cut part of the semiconductor film away from the semiconductor body;

e. if necessary supporting the already freely cut part of the detached semiconductor film and

f. removing the completely detached part of the semiconductor film and passing it into a further processing station or into a storage position.

Such a method is advantageous in particular when the semiconductor film is produced by detachment from an area of a semiconductor block, or if the semiconductor film is produced by tangential detachment from the outer surface of a semiconductor rod. Advantageously, several films can be detached simultaneously by multiple detachment of the outer surface of the semiconductor rod, at positions offset tangentially around the circumference of the semiconductor rod.

The method according to the invention can be used particularly advantageously, if by the bracing of the already detached part of the semiconductor film away from the semiconductor body free space is created for the cutting tool, wherein the free space is formed by the surfaces of the semiconductor body, the tip of the cutting tool and a surface of the braced semiconductor film facing towards the semiconductor.

For the detachment, a pulsed, strongly focused laser beam can be used, and/or a probe with a liquid or gaseous etching medium. It can also be advantageous if the detachment takes place under vacuum or under a special gas atmosphere.

Furthermore it can be of advantage if a focused laser beam modifies the semiconductor material during the detachment and the modified semiconductor material is removed using a liquid or gaseous etching medium.

Semiconductor films can be produced very advantageously in almost any desired length by means of the already mentioned tangential detachment of the outer surface of the semiconductor rod, and by multiple detachment tangentially offset around the circumference of the semiconductor rod, several semiconductor films can be produced simultaneously in almost any desired length.

It is very advantageous moreover if the detachment takes place at a workpiece temperature of more than 200° C.

The method according to the invention can be advantageously carried out with an apparatus having means for bracing the freely cut part of the semiconductor film and means for supporting the freely cut part of the semiconductor film. The means for bracing the freely cut part of the semiconductor film can be constructed as tensioning means and/or compression means, and engage with the freely cut part of the semiconductor film. They can be constructed, for example, as a electrostatic devices and engage with at the freely cut part of the semiconductor film. They can also be constructed however as devices which work with negative pressure or excess pressure. Devices working especially under vacuum, which engage with the freely cut part of the semiconductor film, are advantageous.

The means for supporting the freely cut part of the semiconductor film are advantageously constructed in the form of a support roller and support the already detached part of the semiconductor film in such a way that the bending radius of the braced semiconductor film does not drop below a minimum value.

To this end, it is advantageous if the support roller is constructed in such a way that the braced semiconductor film is only elastically deformed.

A device for carrying out the method can be advantageously realized, for example, if the cutting tool is realized by a pulsed laser, whose pulse length is smaller than 10 e-9 s, wherein the pulsed laser should possess a high beam quality and be strongly focused.

For the surface detachment, a laser with a linear intensity profile can be used.

It can be also advantageous, if a laser is used whose laser beam can be brought close to the processing site in a medium. This medium can be optical fibers.

Furthermore, a fiber laser can be advantageously used. It can be equally advantageous to use a frequency multiplied laser.

With the aid of illustrated embodiments, the invention is now clarified in more detail on the basis of the drawings.

They show:

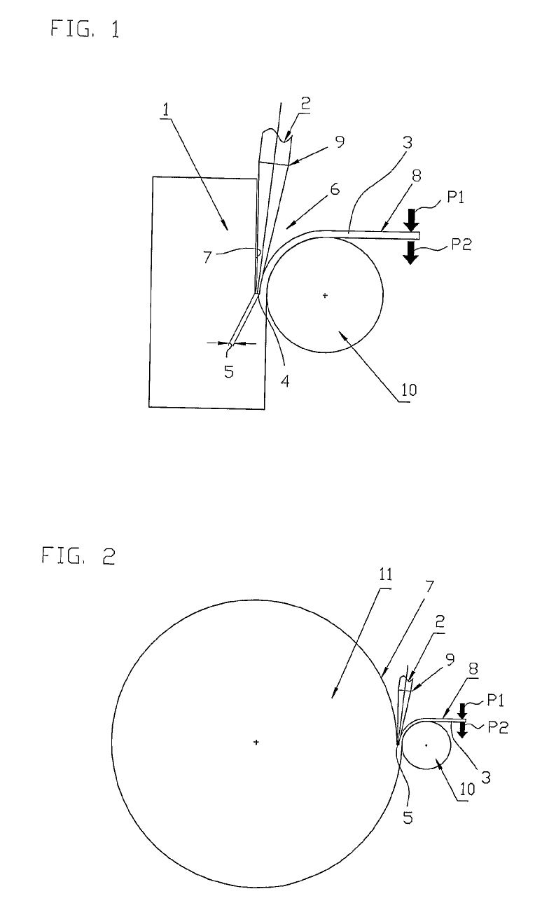

FIG. 1 a schematic diagram of the detachment process;

FIG. 2 a schematic diagram of the tangential detachment;

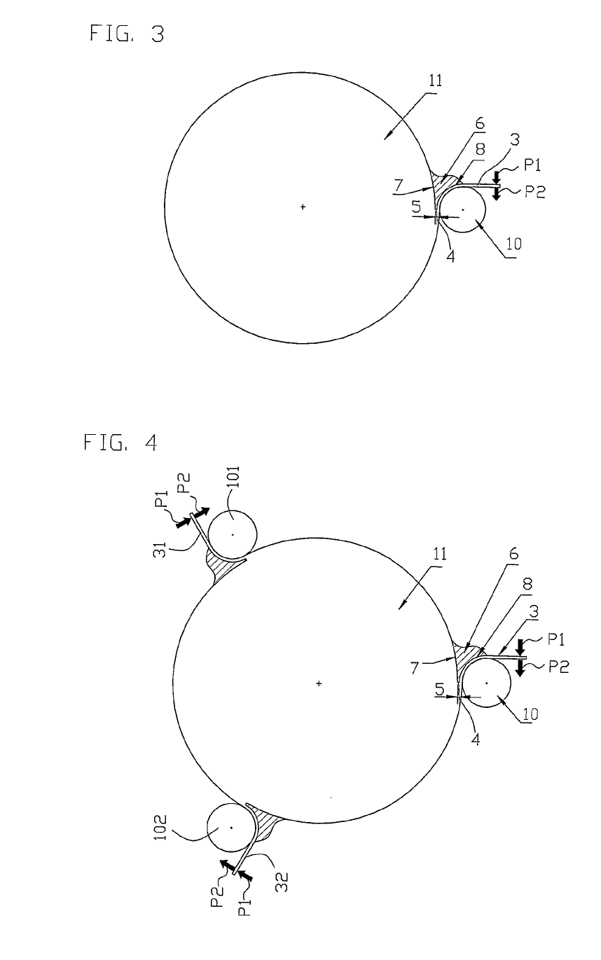

FIG. 3 a schematic diagram of the tangential detachment in accordance with FIG. 2 with free space;

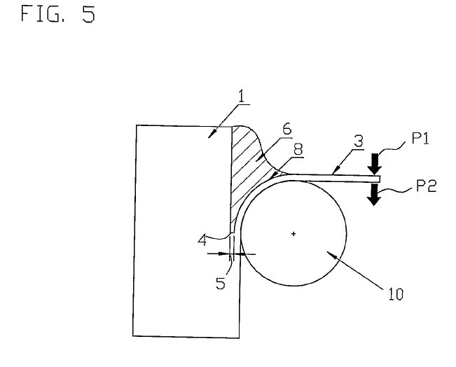

FIG. 4 a schematic diagram of the multiple tangential detachment with free spaces, and

FIG. 5 a schematic diagram of the detachment process in accordance with FIG. 1 with free space.

In FIG. 1, a semiconductor body 1 is shown, highly schematized, that is arranged on a machine tool (not shown) by means of a fixture (also not shown). A cutting tool 2 is located in engagement with the semiconductor body 1 and is used for cutting a semiconductor film 3 from the semiconductor body 1.

Semiconductor bodies, for example a silicon block, consist of a material that is difficult to process because it has a certain brittle hardness. The current processing methods have already been described in detail in the introduction to the description. The cutting tool in accordance with the invention can be embodied as a focused laser beam, an optical fiber tapering to a point as a medium for the laser beam, a probe with an etching medium, a mechanical tool or another suitable cutting tool. In the following, the cutting tool 2 is assumed to be a strongly focused laser beam, which can produce a cut line 4 with only a very small cut line width 5. By means of the bracing of the semiconductor film produced during the cutting 3 according to the invention, a free space 6 is created between the semiconductor body 1 and the detached semiconductor film 3, between the bounding surfaces of which the cutting tool 2 can act. The free space 6 is bounded by the cutting surface 7 on the semiconductor body 1, the tip of the cutting tool 2 and a surface 8 of the braced semiconductor film 3 facing the semiconductor 1, as will be described in more detail in relation to FIG. 5.

The bracing is brought about by means, which exert tensile or compressive forces on the already detached region of the semiconductor film 3. By way of illustration, these tensile or compressive forces are designated by two arrows P1 and P2, wherein the arrow P1 symbolizes the compressive forces and the arrow P2 the tensile forces. The means for bracing the semiconductor film 3 can be realized by mechanically engaging elements, or by contactless engaging elements. It is recommended to perform the bracing by electrostatic means. But the bracing of the semiconductor film can also be realized by means of a vacuum. Likewise, the already detached area of the semiconductor film 3 can be braced by a directed jet of excess air in such a way that the necessary free space 6 is available to the cutting tool 2.

The resulting cut line width of 5 the cut line 4 is no longer determined by the width of the cutting tool 2, rather only by the width of the tip 9 of the cutting tool 2, which can be considerably narrower than, for example, a wire saw, as is used in the prior art for the production of silicon wafers. Accordingly. the wastage of semiconductor material due to cutting decreases considerably, because the cut line width that determines the wastage 5 can be considerably reduced compared to the prior art. When using a strongly focused laser beam as a cutting tool 2, the area-based silicon consumption decreases considerably because the working range, i.e. the cut line width 5, remains restricted to the area around the focus of the cutting tool 2. The creation of the free space required for this is enabled by the bracing of the already freely cut semiconductor film 3 according to the invention. The thinner the detached semiconductor film 3 is, the more flexible it becomes and the better it allows itself to be braced, wherein the limits are set by the elastic deformation of the semiconductor film 3. In order to prevent bending of the braced semiconductor film 3, means for supporting the freely cut part of the semiconductor film 3 are present, that are constructed in the form of a support roller 10 and that brace the already detached part of the semiconductor film 3 in such a way that the bending radius of the braced semiconductor film 3 does not drop below a minimum value. The arrangement and the geometry of the support roller 10 is selected such that the braced semiconductor film 3 is only elastically deformed. The support roller 10 can be arranged to be mobile on a tool carriage, not shown, in such a way that it can follow the line of the cut. This ensures that the already detached section of the semiconductor film 3 is always optimally supported.

FIG. 2 shows how, in an analogous manner to that described in FIG. 1, a film 3 is detached from the outer surface of a semiconductor rod 11. In order to avoid repetitions, identical reference labels are used to refer to equivalent or similarly functioning elements, a detailed description of these equivalent elements being unnecessary. The tip 9 of a strongly focused laser beam as a cutting tool 2 causes the detachment of a semiconductor film 3 from the rotating semiconductor rod 11. By the use of a semiconductor rod 11 as the starting material, the length of the detached film can become very large, theoretically several kilometers. The round shape of a semiconductor rod 11 also permits multiple semiconductor films 3, 31, 32 to be cut from a semiconductor rod 11 simultaneously, which is represented schematically in FIG. 4. The three semiconductor films 3, 31, 32 shown here schematically are supported by three support rollers 10, 101, 102 in the manner already essentially described. Here also, identical reference labels are used to refer to equivalent or similarly functioning elements, so that a repetition of items already described can be avoided.

FIG. 3 shows that a free space 6 is created for the cutting tool 2 near the rotating semiconductor rod 11 by the cutting surface 7 and the surface 11 on the semiconductor film 3 facing the semiconductor rod, without the tip of a tool being shown here. The equivalent applies to the free spaces shown in FIG. 4.

FIG. 5 shows, by reference back to FIG. 1, a free space 6 for a cutting tool, not shown, in accordance with this FIG. 1. Here also, identical reference labels are used to refer to equivalent or similarly functioning elements.

It lies within the scope of the invention that a laser is used advantageously as a cutting tool 2. The beam of the laser is focused using suitable optical means, for example a cylindrical lens or a diffractive optical element, in such a way that a linear intensity profile is created rather than a point-shaped one in order to cut the semiconductor film 3. Furthermore, it is meaningful to place several linear intensity profiles in a row in such a way that a parting line is created across the entire width of the semiconductor body 1, 11, such that the entire cutting line can be removed quasi continuously (at the repetition rate of the laser).

Furthermore, the peripheral beams of the focused laser beam, which face the semiconductor body 1, 11, should ideally extend parallel to the edge of the semiconductor body 1, 11. On the side that faces the semiconductor film 3, 31, 32, near the vicinity of the tip 9 of the cutting tool 2, the peripheral beams follow the bending radius of the semiconductor film 3, 31, 32 and an increasing gap is created as the distance from the focus (the tip of the cutting tool 2) increases.

For cutting silicon by means of femtosecond lasers it is an advantage to work in either in a protective gas atmosphere, in an atmosphere that reacts with the vaporized silicon or in a vacuum. This allows undesired reaction products to be avoided and the surface quality to be improved.

As well as direct laser removal, the semiconductor material, in general silicon, can also first of all be merely modified in the cut line and (mainly modified material) subsequently selectively removed with a gaseous etching medium or an etching fluid.

As a laser source, femtosecond fiber lasers, for example, are suitable. Frequency multiplication is of particular advantage at high efficiency, because for shorter wave lengths the energy density of the ablation threshold is reduced.

An increased temperature of the silicon enhances the removal rate when the ablation is performed with femtosecond lasers.

### LIST OF REFERENCE CODES

1 Semiconductor body
2 Cutting tool
3 Semiconductor film
4 Cut line
5 Cut line width
6 Free space
7 Cutting surface
8 Surface on the semiconductor film
9 Tip of the cutting tool 2
10 Support roller
11 Semiconductor rod
31 Semiconductor film
32 Semiconductor film
101 Support roller
102 Support roller

1. A method for the production of thin semiconductor films, in particular silicon films, by detachment from semiconductor bodies by means of a cutting tool, characterized by the following method steps:
providing a semiconductor body;
moving a cutting tool close to the semiconductor body;
relatively moving the semiconductor body and cutting tool for the successive detachment of the semiconductor film from the semiconductor body;
bracing the already freely cut part of the semiconductor film from the semiconductor body;
supporting the already freely cut part of the detached semiconductor film; and
removing the completely detached part of the semiconductor film and passing it into a further processing station or into a storage position.

2. The method according to claim 1 the production of the semiconductor film takes place by detachment of an area from a semiconductor block.

3. The method according to claim 1 wherein the production of the semiconductor film takes place by tangential detachment of the outer surface of a semiconductor rod.

4. The method according to claim 3 wherein the production of the semiconductor film takes place by multiple detachment of the outer surface of the semiconductor rod, at positions tangentially offset around the circumference of the semiconductor rod.

5. The method according to claim 1 wherein free space is created for the cutting tool by the bracing of the already detached part of the semiconductor film away from the semiconductor body.

6. The method according to claim 5 wherein the free space is formed by the surfaces on the semiconductor body, the tip of the cutting tool and a surface of the brace semiconductor film facing the semiconductor body.

7. The method according to claim 1 wherein a pulsed, strongly focused laser beam is used for the cutting.

8. The method according to claim 1 wherein a probe with a liquid or gaseous etching medium is used for the cutting.

9. The method according to claim 1 wherein the cutting takes place under vacuum or under a special gas atmosphere.

10. The method according to claim 1 wherein for the cutting, a focused laser beam modifies the semiconductor material and the modified semiconductor material is removed with a liquid or gaseous etching medium.

11. The method according to claim 3 wherein by tangential detachment of the outer surface of the semiconductor rod, semiconductor films of almost any length can be produced.

12. The method according to claim 3 wherein by multiple detachment tangentially offset around the circumference of the semiconductor rod, several semiconductor films can be produced simultaneously in almost any desired length.

13. The method according to claim 1 wherein the cutting takes place at a workpiece temperature of more than 200° C.

14. A method for the production of thin semiconductor silicon films wherein the production of the semiconductor film takes place by tangential detachment of the outer surface of a semiconductor rod.

15. An apparatus in particular for carrying out the method according to claim 1 wherein the apparatus has means for bracing the freely cut part of the semiconductor film and means for supporting the freely cut part of the semiconductor film.

16. The apparatus according to claim 15 wherein the means for bracing the freely cut part of the semiconductor film are constructed as tensioning means or compression means, and engage with the freely cut part of the semiconductor film.

17. The apparatus according to claim 16 wherein the means for bracing the freely cut part of the semiconductor film are constructed as electrostatic devices and engage with the freely cut part of the semiconductor film.

18. The apparatus according to claim 16 wherein the means for bracing the freely cut part of the semiconductor film are constructed as devices working under negative pressure or excess pressure and engage with the freely cut part of the semiconductor film.

19. The apparatus according to claim 16 wherein the means for bracing the freely cut part of the semiconductor film are constructed as devices working under vacuum, and engage with the freely cut part of the semiconductor film.

20. The apparatus according to claim 16 wherein the means for bracing the freely cut part of the semiconductor film are constructed as compressed gas devices, and engage with the freely cut part of the semiconductor film.

21. The apparatus according to claim 15 wherein the means for supporting the freely cut part of the semiconductor film are constructed as a support roller, and brace the already detached part of the semiconductor film in such a way that the bending radius of the braced semiconductor film does not drop below a minimum value.

22. The apparatus according to claim 21 wherein the support roller is constructed in such a way that the braced semiconductor film is only elastically deformed.

23. The apparatus according to claim 15 wherein the cutting tool is realized by a pulsed laser, whose pulse length is smaller than 10 e-9 s.

24. The apparatus according to claim 23 wherein the pulsed laser possesses a high beam quality and is strongly focused.

25. The apparatus according to claim 15 wherein a laser with a linear intensity profile is used.

26. The apparatus according to claim 15 wherein a laser is used whose laser beam is brought close to the processing site in a medium.

27. The apparatus according to claim 26 wherein as a medium, optical fibers are used.

28. The apparatus according to claim 15 wherein a fiber laser is used.

29. The apparatus according to claim 15 wherein a frequency multiplied laser is used.

30. The semiconductor film produced according to a method in accordance with claim 1.

31. The semiconductor film according to claim 30 wherein the film is longer than the circumference of the silicon block or rod from which it was detached.

32. The semiconductor film produced by the method according to claim 1 wherein at least two of the three connecting lines between any three points on the film that do not lie on a line and whose surface normals are parallel, have the property that the crystal orientation continuously changes along the connecting lines.

33. A system with a device using a method in accordance with claim 1.

34. A production line with a system in accordance with claim 33.
